(19) United States
(12) Patent Application Publication
(10) Pub. No.: US 2015/0340236 A1
(43) Pub. Date: Nov. 26, 2015

(54) METHOD FOR REDUCING DEFECTS IN POLYSILICON LAYERS

(71) Applicant: MACRONIX INTERNATIONAL CO., LTD., Hsinchu (TW)

(72) Inventors: Jeng Hwa Liao, Hsinchu City (TW); Jung-Yu Shieh, Hsinchu City (TW); Ling Wuu Yang, Hsinchu (TW)

(73) Assignee: MACRONIX INTERNATIONAL CO., LTD., Hsinchu (TW)

(21) Appl. No.: 14/284,162

(22) Filed: May 21, 2014

(51) Int. Cl. H01L 21/28; H01L 21/02; H01L 21/324; H01L 27/115; H01L 21/447

(52) U.S. Cl. CPC H01L 21/28035; H01L 27/11521; H01L 21/447; H01L 21/324; H01L 21/02043

(57) ABSTRACT

Present example embodiments relate generally to semiconductor devices and methods of fabricating a semiconductor device. The method comprises providing a substrate, forming an insulating layer over the substrate, and forming a conductive structure over the insulating layer. The conductive structure is formed by forming a first conductive layer, performing a degassing preparation process over a surface of the first conductive layer to substantially prevent a degassing of the first conductive layer from reaching a second conductive layer, and forming the second conductive layer over the first conductive layer.

### BACKGROUND

The present disclosure relates generally to semiconductor structures, and more specifically, relates to semiconductor devices, including NAND-type and NOR-type devices, and methods of fabricating semiconductor devices.

In general, a memory device may include an array of memory cells formed on a substrate in the form of a series of rows and columns. The memory cells may be accessible by bit lines and word lines appropriately formed within the semiconductor device.

A typical memory cell may include a substrate, a source region, a drain region, a floating gate, and a control gate. A tunnel oxide layer (or gate dielectric layer) may be formed on the substrate so as to separate the floating gate layer from the substrate, the source region, and/or the drain region. Furthermore, a dielectric layer, such as an oxide-nitride-oxide (ONO) layer, may be formed on the floating gate layer so as to separate the floating gate layer from the subsequently formed control gate layer. Field oxide regions may then be formed for the purpose of separating and isolating adjacent memory cells along a word line.

### BRIEF SUMMARY

Despite recent developments in the fabrication of semiconductor devices and the fabricated semiconductor devices, it is recognized in the present disclosure that one or more problems may be encountered in the fabrication of semiconductor devices and the fabricated semiconductor devices.

Present example embodiments relate generally to semiconductor devices and methods of fabricating semiconductor devices that address one or more problems in the fabrication of semiconductor devices and the fabricated semiconductor devices, including those described in the present disclosure.

In an exemplary embodiment, a method of fabricating a semiconductor device is described comprising providing a substrate, forming an insulating layer over the substrate, and forming a conductive structure over the insulating layer. The conductive structure is formed by forming a first conductive layer, performing a degassing preparation process over a surface of the first conductive layer, and forming the second conductive layer over the first conductive layer. The degassing preparation process is operable to substantially prevent a degassing of the first conductive layer from reaching a second conductive layer.

In another exemplary embodiment, a method of fabricating a semiconductor device is described comprising providing a substrate, forming an insulating layer over the substrate, forming a floating gate structure over the insulating layer, forming a second insulating layer over the floating gate structure, and forming a control gate structure over the second insulating layer. The control gate structure is formed over the second insulating layer by forming a first conductive layer, performing a degassing preparation process over a surface of the first conductive layer, and forming the second conductive layer over the first conductive layer. The degassing preparation process operable to substantially prevent a degassing of the first conductive layer from reaching a second conductive layer.

In another exemplary embodiment, a semiconductor device is described comprising a substrate, an insulating layer over the substrate, and a conductive structure over the insulating layer. The conductive structure comprises a first conductive layer and a second conductive layer formed over the first conductive layer. The second conductive layer comprises a substantially reduced density of defects, the defects resulting from a degassing from the formation of the first conductive layer.

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1 is an example illustration of a cross-section of a fabricated semiconductor device;

FIG. 2 is another example illustration of a cross-section of a fabricated semiconductor device comprising a dual layer floating gate structure;

FIG. 3 is an example illustration and example average density of defects (or bumps) on a subsequently formed conductive layer;

FIG. 4 is a flow diagram of an exemplary method for fabricating a semiconductor device;

FIG. 5 is an example illustration of a cross-section of an example embodiment of a fabricated semiconductor device;

FIG. 6 is a flow diagram of an exemplary method for forming a first conductive structure of a semiconductor device;

FIG. 7 is a flow diagram of an exemplary method for performing a preparation process for use in fabricating a semiconductor device;

FIG. 8 is a flow diagram of another exemplary method for performing a preparation process for use in fabricating a semiconductor device;

FIG. 9 is a flow diagram of another exemplary method for performing a preparation process for use in fabricating a semiconductor device; and

FIG. 10 is an example illustration and example average density of defects (or bumps) on a subsequently formed conductive layer using example embodiments.

Although similar reference numbers may be used to refer to similar elements in the figures for convenience, it can be appreciated that each of the various example embodiments may be considered to be distinct variations.

### DETAILED DESCRIPTION

Example embodiments will now be described with reference to the accompanying drawings, which form a part of the present disclosure, and which illustrate example embodiments which may be practiced. As used in the present disclosure and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used in the present disclosure and the appended claims is for the purpose of describing example embodiments only and is not intended to be limitations. In this respect, as used in the present disclosure and the appended claims, the term “in” may include “in” and “on,” and the terms “a,” “an” and “the” may include singular and plural references. Furthermore, as used in the present disclosure and the appended claims, the term “by” may also mean “from,” depending on the context. Furthermore, as used in the present disclosure and the appended claims, the term “if” may also mean “when” or “upon,” depending on the context. Furthermore, as used in the present disclosure and the appended claims, the words “and/or” may refer to and encompass any and all possible combinations of one or more of the associated listed items.

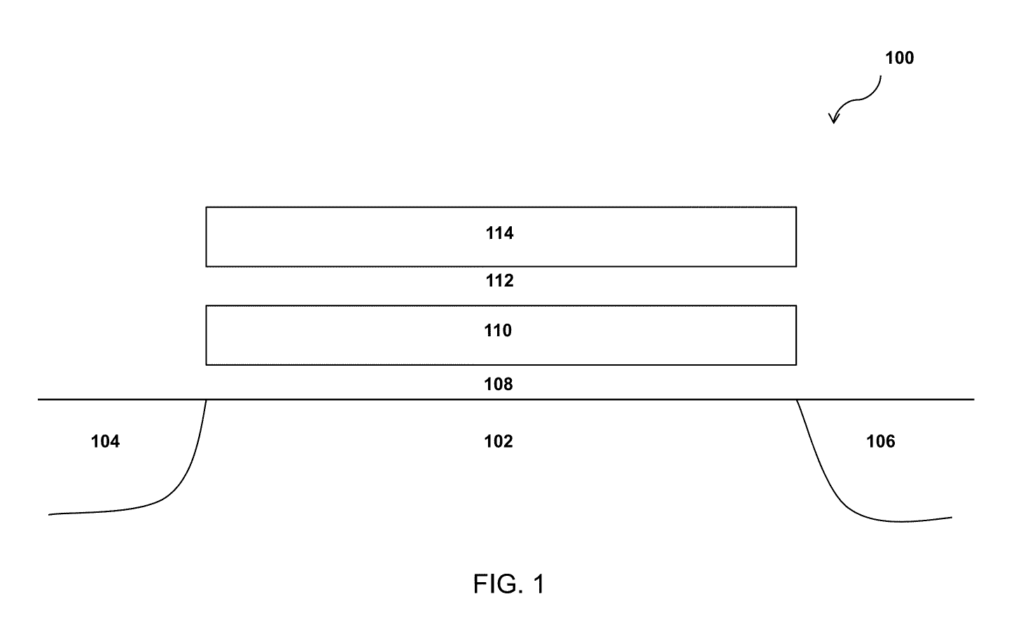

In general, a memory device may include an array of memory cells formed on a substrate in the form of a series of rows and columns. The memory cells may be accessible by bit lines and word lines. A typical memory cell 100, such as a flash memory cell, may include a substrate 102, a source region 104, a drain region 106, a floating gate 110, and a control gate 114, as depicted in the cross-sectional illustration of FIG. 1. A tunnel oxide layer (or gate dielectric layer) 108 may be formed on the substrate 102 so as to separate the subsequently formed floating gate layer 110 from the substrate 102, the source region 104, and/or the drain region 106. Furthermore, a dielectric layer 112, such as an oxide-nitride-oxide (ONO) layer 112, may be formed on the floating gate layer 110 so as to separate the floating gate layer 110 from the subsequently formed control gate layer 114. Field oxide regions 116 (not shown) may then be formed for the purpose of separating and isolating adjacent memory cells along a word line.

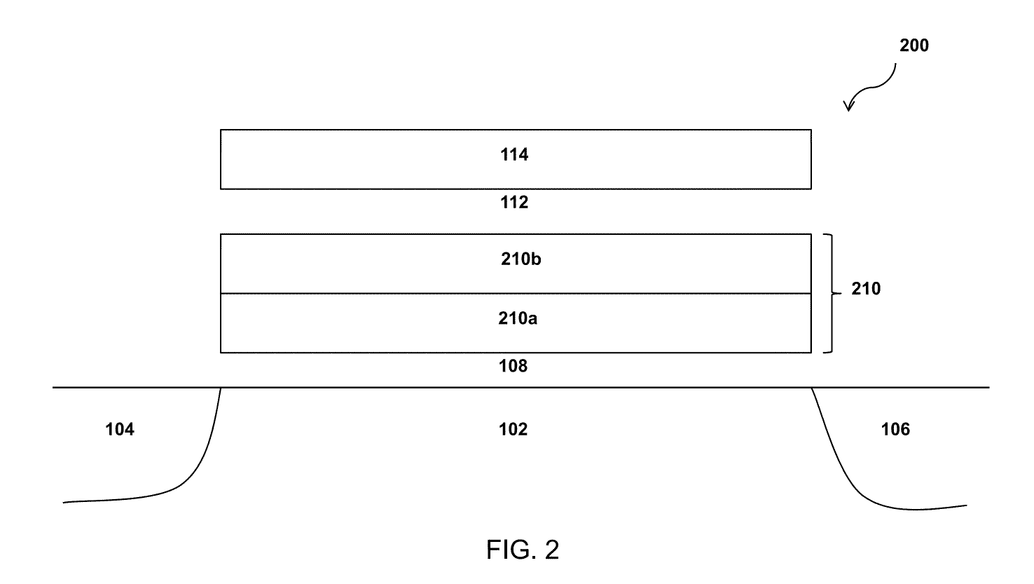

As depicted in the cross-sectional illustration of FIG. 2, recent developments in the fabrication of semiconductor devices 200, including flash memory cells, have improved floating gates 110 having a single layer by providing a dual layer floating gate structure 210 comprising a first polysilicon layer 210a and a second polysilicon layer 210b formed on the first polysilicon layer 210a.

Despite recent developments in semiconductor devices, including flash memory cells, and the fabrication of semiconductor devices, it is recognized in the present disclosure that the fabrication of semiconductor devices and the fabricated semiconductor devices typically encounter one or more problems.

For example, a dual polysilicon layer floating gate structure 210, such as the structure 210 illustrated in FIG. 2, will oftentimes comprise a large number (or average density) of defects (or bumps) formed in and/or on the second polysilicon layer 210b. In general, in the formation of a dual polysilicon layer floating gate structure 210, the first polysilicon layer 210a will first be formed over an insulating layer 108. Thereafter, the second polysilicon layer 210b will be formed over the first polysilicon layer 210a. A pre-cleaning process may be performed on the first polysilicon layer 210a prior to the formation of the second polysilicon layer 210b over the first polysilicon layer 210a. Such a pre-cleaning process typically includes first applying an SC1 solution over the first polysilicon layer 210a, followed by applying an SC2 solution, and finally, applying an HF solution.

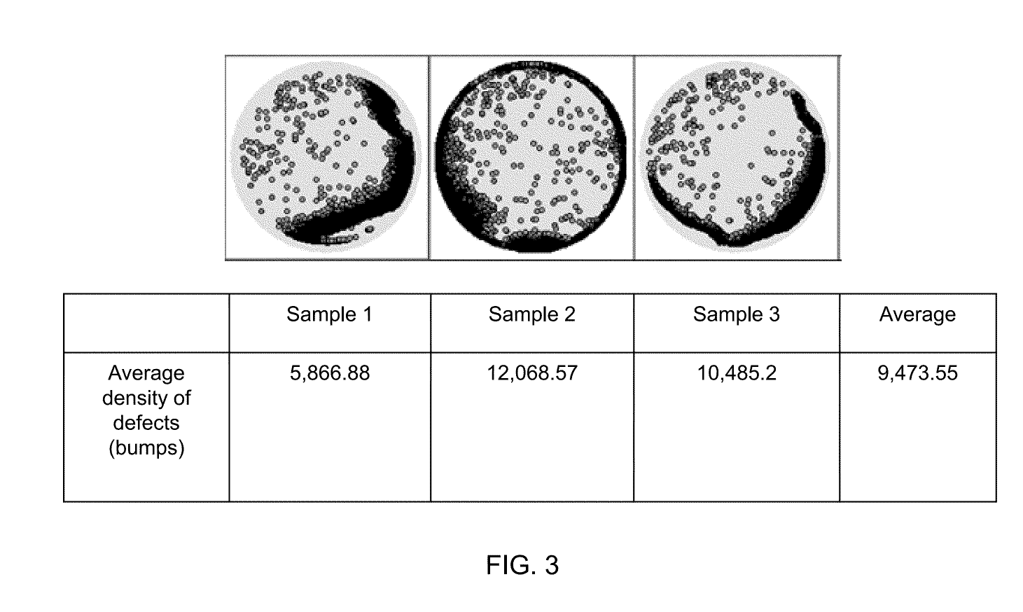

FIG. 3 provides an illustration of the results of three samples of semiconductor devices having a dual layer floating gate structure fabricated using conventional methods. As shown in FIG. 3, the second polysilicon layer of the dual layer floating gate structure of the first fabricated semiconductor device was found to have a large average defect density of about 5,866.88 defects per square cm in the second polysilicon layer. The dual layer floating gate structure of the second fabricated semiconductor device was also found to have a large average defect density of about 12,068.57 defects per square cm in the second polysilicon layer. The dual layer floating gate structure of the third fabricated semiconductor device was also found to have a large average defect density of about 10,485.2 defects per square cm in the second polysilicon layer. Collectively, the dual layer floating gate structure of the fabricated semiconductor devices were found to have a very large average defect density of about 9,473.55 defects per square cm in the second polysilicon layer.

It is recognized in the present disclosure that the aforementioned large average number (or density) of defects (or bumps) in the subsequently formed polysilicon layers, such as the second polysilicon layer 210b illustrated in FIG. 2, of dual- or multi-polysilicon layer floating gate structures, such as the floating gate structure 210 illustrated in FIG. 2, are caused in large part from a degassing, such as a phosphorous degassing, resulting from the formation of the underlying polysilicon layer(s), such as the first polysilicon layer 210a illustrated in FIG. 2. In this regard, it is recognized in the present disclosure that similar problems of the occurrences of large average number of defects (or bumps) may also arise in the fabrication of other conductive structures having two or more contiguous polysilicon layers, including dual- or multilayer floating gate structures and dual- or multilayer control gate structures (such as floating or control gate structures having two or more contiguous polysilicon layers).

Semiconductor devices, including NAND-type devices and NOR-type devices, and methods of fabricating semiconductor devices are described in the present disclosure for addressing one or more problems discovered in the fabrication of semiconductor devices and fabricated semiconductor devices, including those described in the present disclosure. It is to be understood in the present disclosure that the principles described can be applied outside of the context of NAND-type devices and NOR-type devices described in exemplary embodiments without departing from the teachings of the present disclosure.

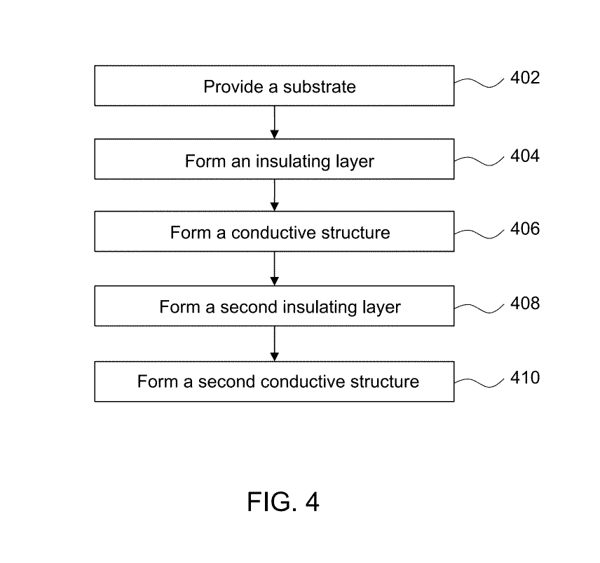

As illustrated in the flow diagram of FIG. 4, an example embodiment of a method 400 of fabricating a semiconductor device comprises providing a substrate 402, forming an insulating layer over at least a portion of the substrate 404, and forming a conductive structure over the insulating layer 406. The conductive structure may include a single-, dual-, or multi-polysilicon layer floating gate structure. The method may further comprise forming a second insulating layer over the conductive structure 408. The method may further comprise forming a second conductive structure over the second insulating layer 410. The second conductive structure may include a single- or dual-polysilicon layer control gate structure.

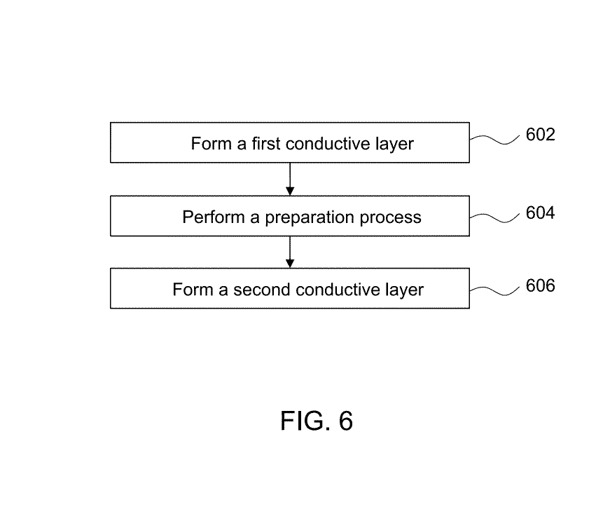

As illustrated in FIG. 6, in respect to the forming of the conductive structure 406 (and/or the forming of the second conductive structure 410), the conductive structure 406 (and/or the second conductive structure 410) may be formed by forming a first conductive layer 602 over at least a portion of the insulating layer (or the second insulating layer for the second conductive structure 410), performing a preparation process 604 on at least a portion of the conductive structure, and forming a second conductive layer 606 over (or after) at least a portion of the first conductive layer.

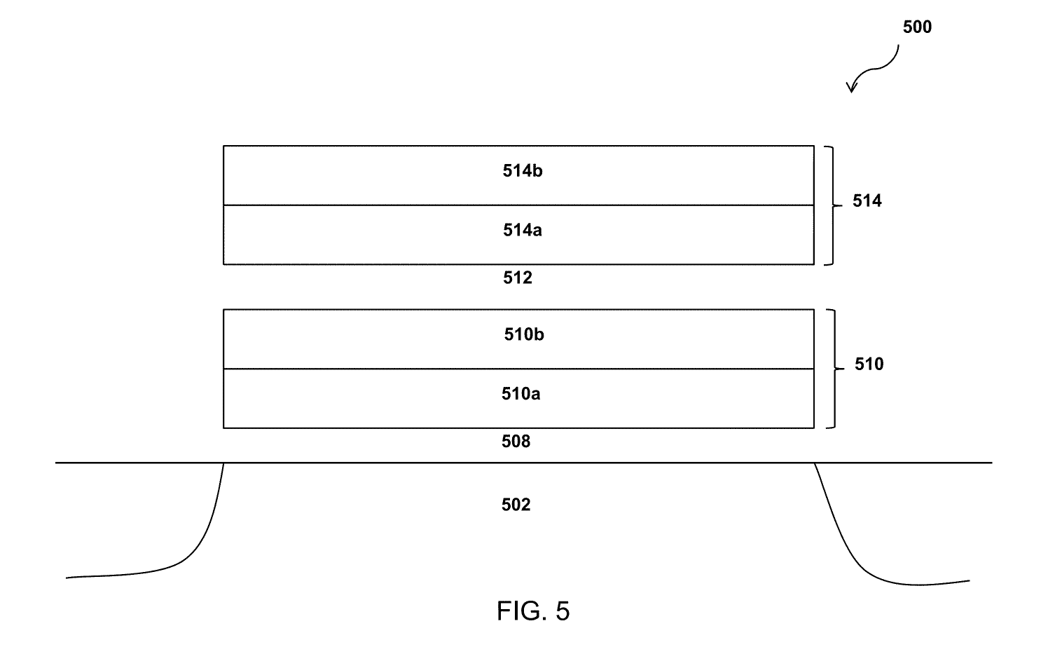

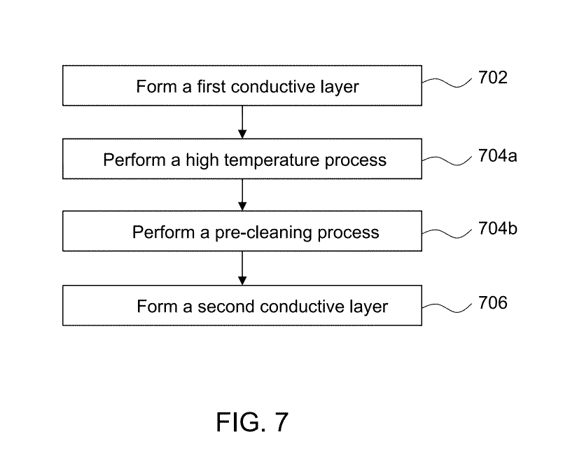

In respect to the preparation process 604 for use in fabricating a semiconductor device, an example embodiment of which is illustrated in FIG. 5 and FIG. 7, after the forming 702 of a first conductive layer 510a of the conductive structure 510 (and/or the first conductive layer 514a of the second conductive structure 514), an example embodiment of the preparation process 604 and 700 may comprise performing a high temperature process 704a and performing a pre-cleaning process 704b before the forming 706 of the second conductive layer 510b of the conductive structure 510 (and/or the second conductive layer 514b of the second conductive structure 514).

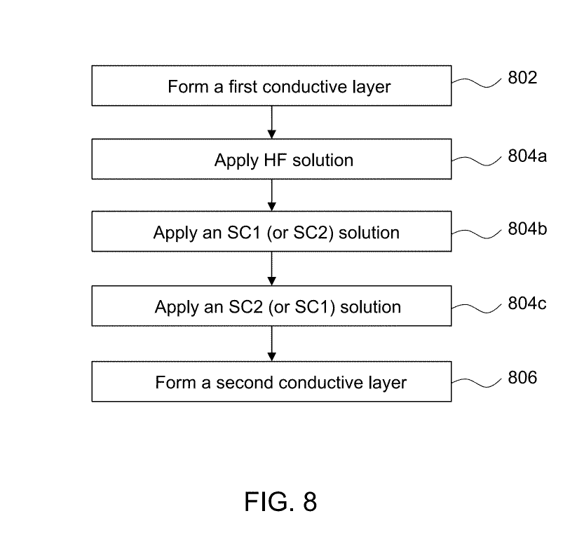

In another example embodiment of the preparation process for use in the fabrication of a semiconductor device, as illustrated in the example embodiment of FIG. 5 and FIG. 8, after the forming 802 of the first conductive layer 510a of the conductive structure 510 (and/or the first conductive layer 514a of the second conductive structure 514), an example embodiment of the preparation process 604 and 800 may comprise applying an HF solution 804a, applying an SC1 solution (or SC2 solution) 804b, and applying 804c an SC2 solution (or SC1 solution) as a last applying step before the forming 806 of the second conductive layer 510b of the conductive structure 510 (and/or the second conductive layer 514b of the second conductive structure 514).

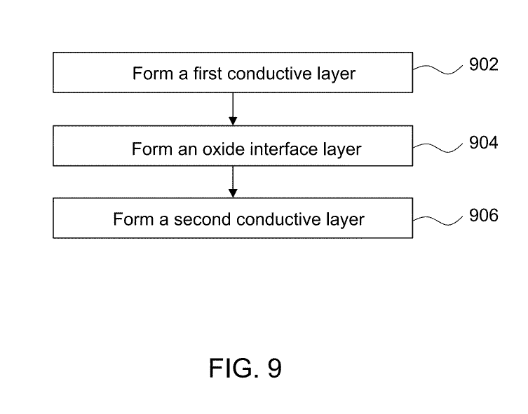

In another example embodiment of the preparation process for use in the fabrication of a semiconductor device, as illustrated in the example embodiment of FIG. 5 and FIG. 9, after the forming 902 of the first conductive layer 510a of the conductive structure 510 (and/or the first conductive layer 514a of the second conductive structure 514), an example embodiment of the preparation process 604 or 900 may comprise forming 904 an oxide layer (not shown) over at least a portion of the first conductive layer 510a of the conductive structure 510 (and/or the first conductive layer 514a of the second conductive structure 514) before the forming 906 of the second conductive layer 510b of the conductive structure 510 (or the second conductive layer 514b of the second conductive structure 514).

Example embodiments of the methods of fabricating a semiconductor device and example embodiments of the fabricated semiconductor device will now be described below with references to the methods illustrated in at least FIGS. 4 and 6 to 9 and the device illustrated in at least FIG. 5.

(1) Providing a Substrate (e.g., Action 402).

Substrates, such as the substrate 502, suitable for use in semiconductor devices, such as the semiconductor device 500, may be obtained by any one of many manufacturing methods, such as pressing methods, float methods, down-drawn methods, redrawing methods, fusion methods, or the like.

(2) Forming an Insulating Layer (e.g., Action 404).

An insulating layer, such as insulating layer 508, may be formed on a substrate, such as the substrate 502 obtained from the above action 402, as illustrated in the cross-sectional view of the example embodiment in FIG. 5. The insulating layer 508 may be operable to isolate the substrate 502 from a subsequent forming of a conductive structure, such as conductive structure 510 (as described in No. 3 below), and/or any other subsequently formed layers/structures, and/or may also act as an etch stop in any subsequent patterning or etching processes. The insulating layer 508 formed may be formed to about 75 Angstroms in thickness. It is recognized herein that the insulating layer 508 may be formed to any desired thickness and composition, including about 50 to about 100 Angstroms in thickness, and the insulating layer 508 may include an oxide layer in example embodiments.

(3) Forming a Conductive Structure (e.g., Action 406).

As illustrated in the cross-sectional view of FIG. 5, a conductive structure, such as the dual polysilicon layer conductive structure 510, may be formed 406 on an insulating layer, such as the insulating layer 508 formed in action 404. The conductive structure 510 may comprise two or more conductive layers, such as the first conductive layer 510a and the second conductive layer 510b. It is to be understood in the present disclosure that the conductive structure 510 may comprise one, two, or more than two conductive layers without departing from the teachings of the present disclosure. The two or more conductive layers (such as 510a and/or 510b) may be substantially crystalline polysilicon layers, and may be formed by, for example, low pressure chemical vapor deposition (LPCVD) and doped via, for example, diffusion doping or ion implantation doping techniques to create different doping concentration or crystalline characteristic. The thickness of each of the conductive layers (such as 510a and/or 510b) may be formed to about 500 Angstroms, and the collective thickness of the conductive structure 510 may be formed to about 1300 Angstroms. It is recognized herein that the thickness of each of the conductive layers (such as 510a and/or 510b) may be formed to about 200 to about 1500 Angstroms and the thickness of the conductive structure 510 may be formed to about 500 to about 2500 Angstroms in example embodiments. In example embodiments, the conductive structure 510 may be a dual and/or multi layer floating gate structure of a semiconductor device, such as a NAND-type device or a NOR-type device.

An example embodiment of forming 406 the conductive structure, such as conductive structure 510, is illustrated in FIG. 6 and further explained in the below actions in Nos. 3a-e.

(3a) Forming a First Conductive Layer (e.g. Action 602)

A first conductive layer, such as a polysilicon layer 510a, may be formed 602 over at least a portion of an insulating layer, such as the insulating layer 508 formed in action 404. A preparation process 604 may then be performed after the formation 602 of the first conductive layer 510a. Example embodiments of the preparation process 604 will now be described below.

(3b) Preparation Process Including a High Temperature Process (e.g., Action 604 and/or Process 700)

In an example embodiment of a preparation process 604 and/or 700, as illustrated in FIG. 7, after the first conductive layer 510a is formed 602 and 702, a high temperature process 704a may be performed. The high temperature process 704a may include any high temperature process, including a rated thermal process (RTP) and/or annealing process. In an example embodiment, the high temperature process 704a may be performable at a temperature of about 700 Celsius to about 1100 Celsius, under a pressure of about 1 Torr to about 760 Torr, and for a duration of about 1 to about 150 seconds. It is recognized in the present disclosure that the high temperature process 704a performable after the formation of a conductive layer (such as the formation 602 and 702 of the first conductive layer 510a) may be operable to at least increase the rate of degassing resulting from the formation (such as the formation 602 and 702) of the conductive layer (such as the first conductive layer 510a) and at least assist in substantially reducing the occurrence of (or average density of) defects (or bumps) formable in and/or on a subsequently formed conductive layers (such as the second conductive layer 510b of the conductive structure 510).

In example embodiments, a pre-cleaning process 704b may also be performable before or after the above high temperature process 704a. An example embodiment of the pre-cleaning process 704b may be performable after the high temperature process 704a and comprise first applying an SC1 solution (or SC2 solution), applying an SC2 solution (or SC1 solution), and applying an HF solution as a last applying step before the forming 706 of the second conductive layer 510b of the conductive structure 510.

The SC1 solution may comprise NH₄OH, H₂O₂, and deionized water in a ratio between about ½ to about 4/1, and the applying the SC1 solution is performed at a temperature between about 15 to about 80 Celsius. The SC2 solution may comprise HCl, H₂O₂, and deionized water in a ratio between about 1/2 to about 4/1, and the applying the SC2 solution is performed at a temperature between about 15 to about 80 Celsius. The HF solution may comprise about 49% concentration of HF and deionized water in a ratio between about 1/50 to about 1/500, and the applying the HF solution is performed at a temperature between about 15 to about 45 Celsius.

In an example embodiment, the pre-cleaning process 704b may be performed before or replaceable by a process, such as the process 800 illustrated in FIG. 8, comprising applying an SC1 solution or SC2 solution as a last applying step before the forming 706 of the second conductive layer 510b of the conductive structure 510. For example, the process 800 may comprise first applying an HF solution, applying an SC1 solution (and/or SC2 solution), and applying an SC2 (and/or SC1 solution) as a last applying step before the forming 606 and 706 of the second conductive layer 510b of the conductive structure 510. It is recognized in the present disclosure that such a process of applying an SC1 solution and/or SC2 solution as the last applying step before the forming 606 and 706 of the second conductive layer 510b, such as the process illustrated in FIG. 8, may be operable to form an oxide layer (not shown) over at least a portion of the first conductive layer 510a so as to substantially block or prevent a degassing from the formation 702 and 802 of the first conductive layer 510a from reaching the second conductive layer 510b. In this regard, such a process 800 may be operable to at least assist in substantially reducing the occurrence of (or average density of) defects (or bumps) formable in and/or on the subsequently formed second conductive layer 510b of the conductive structure 510.

(3c) Preparation Process Including a Last Applying Step of Applying an SC1 Solution or SC2 Solution (e.g., Action 604 and/or Process 800)

In another example embodiment, as illustrated in FIG. 8, after the conductive layer (such as the first conductive layer 510a) is formed 602 and 802, the preparation process 604 and/or 800 may comprise applying an SC1 solution and/or SC2 solution as a last applying step before the forming 606 and 806 of the subsequent conductive layer (such as the second conductive layer 510b) of the conductive structure 510. For example, the process 800 may comprise first applying an HF solution 804a, applying an SC1 solution (and/or SC2 solution) 804b, and applying an SC2 (and/or SC1 solution) as a last applying step 804c before the forming 606 and 806 of the second conductive layer 510b of the conductive structure 510. It is recognized in the present disclosure that such a process of applying an SC1 solution and/or SC2 solution as the last applying step before the forming 606 and 806 of the second conductive layer 510b, such as the process illustrated in FIG. 8, may be operable to form an oxide layer (not shown) over at least a portion of the first conductive layer 510a so as to substantially block or prevent a degassing from the formation 602 and 802 of the first conductive layer 510a from reaching the second conductive layer 510b. In this regard, such a process may be operable to at least assist in substantially reducing the occurrence of (or average density of) defects (or bumps) formable in and/or on the subsequently formed conductive layer (such as the second conductive layer 510b of the conductive structure 510).

(3d) Preparation Process Including Forming an Oxide Interface (e.g., Action 604 and/or Process 900)

In an example embodiment of a preparation process 604 and/or 900, as illustrated in FIG. 9, after the first conductive layer 510a is formed 602 and 902, an oxide interface (not shown) may be formed 904 over at least a portion of the first conductive layer 510a of the conductive structure 510. It is recognized in the present disclosure that the above process 904 of forming an oxide interface may be performable after the high temperature process 704a and/or process 800 in example embodiments. It is recognized in the present disclosure that a process 900, such as the example illustrated in FIG. 9, of forming 904 an oxide interface layer (not shown) over at least a portion of the first conductive layer 510a may be operable to substantially block and/or prevent a degassing caused by the formation 602 and 902 of the first conductive layer 510a from reaching the subsequently formed second conductive layer 510b. In this regard, such a process 904 may be operable to at least assist in substantially reducing the occurrence of (or average density of) defects (or bumps) formable in and/or on the subsequently formed second conductive layer 510b of the conductive structure 510.

It is to be understood in the present disclosure that one or more of the preparation processes 604, 700, 800, and/or 900 may be performable alone and/or in combination with other preparation processes 604, 700, 800, and/or 900 without departing from the teachings of the present disclosure.

(3e) Forming a Second Conductive Layer (e.g. Action 606)

After performing the preparation process 604, such as the one or more above example embodiments of the preparation process 700, 800, and/or 900, a second conductive layer, such as a polysilicon layer 510b, may be formed 606, 706, 806, and/or 90 over at least a portion of (or after) the first conductive layer 510a.

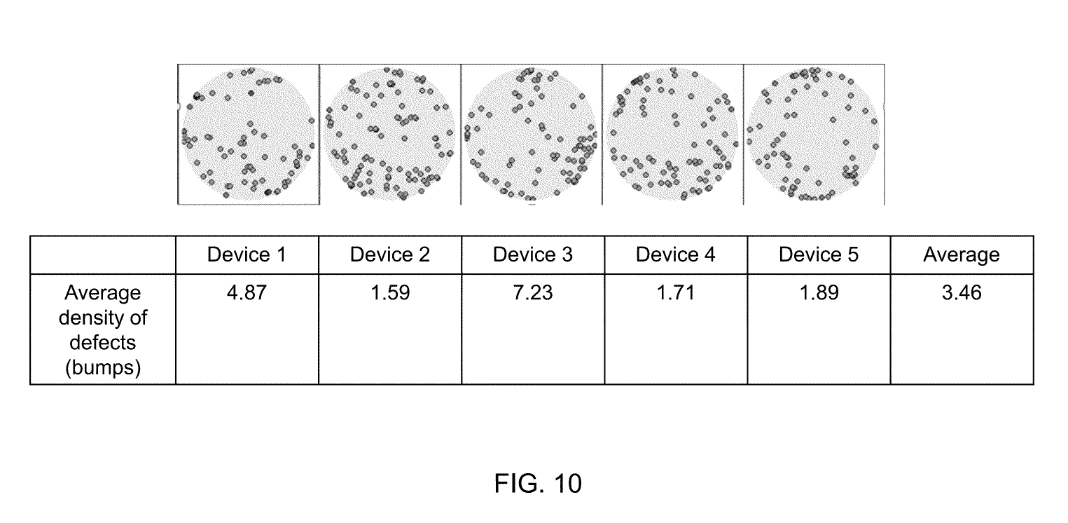

FIG. 10 provides an illustration of the results of five example semiconductor devices fabricated using example embodiments. As shown in FIG. 10, the first semiconductor device was found to have a substantially reduced average defect density of about 4.87 defects per square cm in the second polysilicon layer. The second semiconductor device was also found to have a substantially reduced average defect density of about 1.59 defects per square cm in the second polysilicon layer. The third semiconductor device was also found to have a substantially reduced average defect density of about 7.23 defects per square cm in the second polysilicon layer. The fourth semiconductor device was also found to have a substantially reduced average defect density of about 1.71 defects per square cm in the second polysilicon layer. The fifth semiconductor device was also found to have a substantially reduced average defect density of about 1.89 defects per square cm in the second polysilicon layer. Collectively, the five example embodiments of the semiconductor device fabricated using example embodiments were found to have a substantially reduced average defect density of about 3.46 defects per square cm in the second polysilicon layer as compared to the average defect density of about 9,473.55 defects per square cm for conventional semiconductor devices fabricated using conventional methods. It should of course be understood that the measured defect densities are provided for illustrative purposes, and that effective implementations of the claimed embodiments may have minor or substantively differing results depending on the processing parameters and materials used, and that accordingly the measured defect density performances, including comparisons between example embodiments and other methods, should not be used to limit the scope of any example embodiments ultimately claimed in a patent that may stem from the present application.

It is to be understood in the present disclosure that one or more of the preparation processes 604, 700, 800, and/or 900 may also be performable, either alone or in combination with other preparation processes 604, 700, 800, and/or 900, on (or after the formation of) the second conductive layer 510b in example embodiments. In this regard, example embodiments of the aforementioned one or more preparation processes 604, 700, 800, and/or 900 may be performable when the second conductive layer 510b is the last conductive layer of the conductive structure 510 and/or when the conductive structure 510 comprises one, two, or more than two conductive layers, including when the second conductive layer 510b is not the last conductive layer of the conductive structure 510.

(4) Forming an Insulating Layer (e.g. Action 408)

An insulating layer 512 may be formed 408 over the conductive polysilicon structure 510. The thickness of the insulating layer 508 may be about 75 Angstroms. It is recognized herein that the thickness of the insulating layer 508 may be about 50 to about 100 Angstroms in example embodiments.

(5) Forming a Second Conductive Structure (e.g., Action 410).

As illustrated in the cross-sectional view of FIG. 5, a second conductive structure, such as the dual polysilicon layer conductive structure 514, may be formed 410 on an insulating layer, such as the insulating layer 512 formed in action 408. The second conductive structure 514 may comprise two or more conductive layers, such as the first conductive layer 514a and the second conductive layer 514b. It is to be understood in the present disclosure that the conductive structure 514 may comprise one, two, or more than two conductive layers without departing from the teachings of the present disclosure. The two or more conductive layers (such as 514a and/or 514b) may be substantially crystalline polysilicon layers, and may be formed by, for example, low pressure chemical vapor deposition (LPCVD) and doped via, for example, diffusion doping or ion implantation doping techniques to create different doping concentration or crystalline characteristic. The thickness of each of the conductive layers (such as 514a and/or 514b) may be formed to about 500 Angstroms, and the collective thickness of the second conductive structure 514 may be formed to about 1300 Angstroms. It is recognized herein that the thickness of each of the conductive layers (such as 514a and/or 514b) may be formed to about 200 to about 1500 Angstroms and the thickness of the second conductive structure 514 may be formed to about 500 to about 2500 Angstroms in example embodiments. In example embodiments, the second conductive structure 514 may be a dual and/or multi layer control gate structure of a semiconductor device, such as a NAND-type device or a NOR-type device.

An example embodiment of forming 410 the second conductive structure, such as the second conductive structure 514, may be performed in substantially the same manner as the forming 406 of the first conductive structure 510 illustrated in FIG. 6. An example process of forming 410 the second conductive structure, such as the second conductive structure 514, is described below in Nos. 5a-e.

(5a) Forming a First Conductive Layer (e.g. Action 602)

A first conductive layer, such as a polysilicon layer 514a, for the second conductive structure 514 may be formed 602 over at least a portion of an insulating layer, such as the insulating layer 512 formed in action 408. A preparation process 604 may then be performed after the formation 602 of the first conductive layer 514a of the second conductive structure 514. Example embodiments of the preparation process 604 will now be described below for the first conductive layer 514a.

(5b) Preparation Process Including a High Temperature Process (e.g., Action 604 and/or Process 700)

In an example embodiment of a preparation process 604 and/or 700, as illustrated in FIG. 7, after the first conductive layer 514a is formed 602 and 702, a high temperature process 704a may be performed. The high temperature process 704a may include any high temperature process, including a rated thermal process (RTP) and/or annealing process. In an example embodiment, the high temperature process 704a may be performable at a temperature of about 700 Celsius to about 1100 Celsius, under a pressure of about 1 Torr to about 760 Torr, and for a duration of about 1 to about 150 seconds. It is recognized in the present disclosure that the high temperature process 704a performable after the formation of a conductive layer (such as the formation 602 and 702 of the first conductive layer 510a) may be operable to at least increase the rate of degassing resulting from the formation (such as 602 and 702) of the conductive layer (such as the first conductive layer 514a of the second conductive structure 514), and at least assist in substantially reducing the occurrence of (or average density of) defects (or bumps) formable in and/or on the subsequently formed conductive layer (such as the second conductive layer 514b of the second conductive structure 514).

In example embodiments, a pre-cleaning process 704b may also be performable before or after the above high temperature process 704a. An example embodiment of the pre-cleaning process 704b may be performable after the high temperature process 704a and comprise first applying an SC1 solution (or SC2 solution), applying an SC2 solution (or SC1 solution), and applying an HF solution as a last applying step before the forming 706 of the second conductive layer 514b of the second conductive structure 514.

The SC1 solution may comprise NH₄OH, H₂O₂, and deionized water in a ratio between about 1/2 to about 4/1, and the applying the SC1 solution is performed at a temperature between about room temperature to about 80 Celsius. The SC2 solution may comprise HCl, H₂O₂, and deionized water in a ratio between about 1/2 to about 4/1, and the applying the SC2 solution is performed at a temperature between about room temperature to about 80 Celsius. The HF solution may comprise about 49% concentration of HF and deionized water in a ratio between about 1/50 to about 1/500, and the applying the HF solution is performed at a temperature between about room temperature to about 45 Celsius.

In an example embodiment, the pre-cleaning process 704b may be performed before or replaceable by a process, such as the process 800 illustrated in FIG. 8, comprising applying an SC1 solution or SC2 solution as a last applying step before the forming 706 of the second conductive layer 514b of the second conductive structure 514. For example, the process 800 may comprise first applying an HF solution, applying an SC1 solution (and/or SC2 solution), and applying an SC2 (and/or SC1 solution) as a last applying step before the forming 606 and 706 of the second conductive layer 514b of the second conductive structure 514. It is recognized in the present disclosure that such a process of applying an SC1 solution and/or SC2 solution as the last applying step before the forming 606 and 706 of the second conductive layer 514b, such as the process illustrated in FIG. 8, may be operable to form an oxide layer (not shown) over at least a portion of the first conductive layer 514a so as to substantially block or prevent a degassing from the formation 702 and 802 of the first conductive layer 514a from reaching the second conductive layer 514b. In this regard, such a process 800 may be operable to at least assist in substantially reducing the occurrence of (or average density of) defects (or bumps) formable in and/or on the subsequently formed second conductive layer 514b of the second conductive structure 514.

(5c) Preparation Process Including a Last Applying Step of Applying an SC1 Solution or SC2 Solution (e.g., Action 604 and/or Process 800)

In another example embodiment, as illustrated in FIG. 8, after the first conductive layer 514a of the second conductive structure 514 is formed 602 and 802, the preparation process 604 and/or 800 may comprise applying an SC1 solution and/or SC2 solution as a last applying step before the forming 606 and 806 of the second conductive layer 514b of the second conductive structure 514. For example, the process 800 may comprise first applying an HF solution 804a, applying an SC1 solution (and/or SC2 solution) 804b, and applying an SC2 (and/or SC1 solution) as a last applying step 804c before the forming 606 and 806 of the second conductive layer 514b of the second conductive structure 514. It is recognized in the present disclosure that such a process of applying an SC1 solution and/or SC2 solution as the last applying step before the forming 606 and 806 of the second conductive layer 514b, such as the process illustrated in FIG. 8, may be operable to form an oxide layer (not shown) over at least a portion of the first conductive layer 514a so as to substantially block or prevent a degassing from the formation 602 and 802 of the first conductive layer 514a from reaching the second conductive layer 514b. In this regard, such a process may be operable to at least assist in substantially reducing the occurrence of (or average density of) defects (or bumps) formable in and/or on the subsequently formed conductive layer (such as the second conductive layer 514b of the second conductive structure 514).

(5d) Preparation Process Including Forming an Oxide Interface (e.g., Action 604 and/or Process 900)

In an example embodiment of a preparation process 604 and/or 900, as illustrated in FIG. 9, after the first conductive layer 514a is formed 602 and 902, an oxide interface (not shown) may be formed 904 over at least a portion of the first conductive layer 514a of the second conductive structure 514. It is recognized in the present disclosure that the above process 904 of forming an oxide interface may be performable after the high temperature process 704a and/or process 800 in example embodiments. It is recognized in the present disclosure that a process 900, such as the example illustrated in FIG. 9, of forming 904 an oxide interface layer (not shown) over at least a portion of the first conductive layer 514a may be operable to substantially block and/or prevent a degassing caused by the formation 602 and 902 of the first conductive layer 514a from reaching the subsequently formed second conductive layer 514b. In this regard, such a process 904 may be operable to at least assist in substantially reducing the occurrence of (or average density of) defects (or bumps) formable in and/or on the subsequently formed second conductive layer 514b of the second conductive structure 514.

It is to be understood in the present disclosure that one or more of the preparation processes 604, 700, 800, and/or 900 may be performable alone and/or in combination with other preparation processes 604, 700, 800, and/or 900 without departing from the teachings of the present disclosure.

(5e) Forming a Second Conductive Layer (e.g. Action 606)

After performing the preparation process 604, such as the one or more above example embodiments of the preparation process 700, 800, and/or 900, a second conductive layer, such as a polysilicon layer 514b, may be formed 606, 706, 806, and/or 90 over at least a portion of (or after) the second conductive layer 514a.

It is to be understood in the present disclosure that one or more of the preparation processes 604, 700, 800, and/or 900 may also be performable, either alone or in combination with other preparation processes 604, 700, 800, and/or 900, on (or after the formation of) the second conductive layer 514b of the second conductive structure 514 in example embodiments. In this regard, example embodiments of the aforementioned one or more preparation processes 604, 700, 800, and/or 900 may be performable when the second conductive layer 514b is the last conductive layer of the second conductive structure 514 and/or when the conductive structure 514 comprises one, two, or more than two conductive layers, including when the second conductive layer 514b is not the last conductive layer of the second conductive structure 514.

It is also to be understood in the present disclosure that one or more of the preparation processes 604, 700, 800, and/or 900 may be performable, either alone or in combination with other preparation processes 604, 700, 800, and/or 900, on (or after the formation of) one or more conductive layers (not shown) of other conductive structures (not shown), including in semiconductor devices wherein there are more than two conductive structures in addition to conductive structure 510 and second conductive structure 514. For example, one or more of the preparation processes 604, 700, 800, and/or 900 may be performable, either alone or in combination with other preparation processes 604, 700, 800, and/or 900, on (or after the formation of) one or more conductive layers (not shown) of a third conductive structure (not shown) and other conductive structures (not shown).

While various embodiments in accordance with the disclosed principles have been described above, it should be understood that they have been presented by way of example only, and are not limiting. Thus, the breadth and scope of the example embodiments described in the present disclosure should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

For example, as referred to in the present disclosure, “forming” a layer, multilayer, and/or structure may include any method of creating the layer, multilayer, and/or structure, including depositing and the like. A “dual” or “multi” layer and/or structure may be one composite layer, structure, and/or stack comprising a plurality of internal layers and/or a plurality of layers, multilayers, structures, and/or stacks stacked or formed on or over one another. Internal structures may include any internal structure of a semiconductor device, including floating gate layers/structures, control gate layers/structures, other structures in NAND-type devices, other structures in NOR-type devices, charge storage structures such as silicon-oxide-nitride-oxide-silicon (SONOS), and/or bandgap engineered silicon-oxide-nitride-oxide-silicon (BE-SONOS) structures comprising a tunneling dielectric layer, a trapping layer, and a blocking oxide layer.

Although one or more layers, multilayers, and/or structures may be described in the present disclosure as being “silicon,” “polysilicon,” “conductive,” “oxide,” and/or “insulative” layers, multilayers, and/or structures, it is to be understood that example embodiments may be applied for other materials and/or compositions of the layers, multilayers, and/or structures. Furthermore, such structures may be in the form of a crystalline structure and/or amorphous structure in example embodiments.

Furthermore, “etching” or “patterning” of one or more layers, multilayers, and/or structures may include any method of creating a desired pattern on the one or more layers, multilayers, and/or structures, including performing a photolithography process by applying a photoresist mask (not shown) having pre-formed patterns and etching the layers, multilayers, and/or structures according to the pre-formed patterns on the photoresist mask.

“Defects” or “bumps” formed in and/or on material(s), layer(s), and/or between materials and/or layers may include openings, bores, gaps, voids, cracks, holes, bubbles, bumps, and the like, comprising air, other gases, and/or compositions other than the material and/or compositions of its surrounding material and/or layer(s), and/or a mixture thereof. Furthermore, although the present disclosure describes example embodiments for addressing “defects” or “bumps,” the claimed approaches described in the present disclosure may also be beneficially applicable to address and/or improve other performance-related problems and/or issues, including formation, shifting, changing in size, changing in shape, changing in composition, combining, dividing, and/or migrating of other types of imperfections in the semiconductor fabrication process.

It is to be understood in the present disclosure that the principles described can be applied outside the context of NAND-type devices described in exemplary embodiments, including NOR-type devices, other memory storage devices, floating gate memory devices, charge trapping memory devices, non-volatile memory devices, and/or embedded memory devices.

Various terms used herein have special meanings within the present technical field. Whether a particular term should be construed as such a “term of art” depends on the context in which that term is used. “Connected to,” “forming on,” “forming over,” or other similar terms should generally be construed broadly to include situations where formations, depositions, and connections are direct between referenced elements or through one or more intermediaries between the referenced elements. These and other terms are to be construed in light of the context in which they are used in the present disclosure and as one of ordinary skill in the art would understand those terms in the disclosed context. The above definitions are not exclusive of other meanings that might be imparted to those terms based on the disclosed context.

Words of comparison, measurement, and timing such as “at the time,” “equivalent,” “during,” “complete,” and the like should be understood to mean “substantially at the time,” “substantially equivalent,” “substantially during,” “substantially complete,” etc., where “substantially” means that such comparisons, measurements, and timings are practicable to accomplish the implicitly or expressly stated desired result.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method of fabricating a semiconductor device, the method comprising:
providing a substrate;
forming an insulating layer over the substrate; and
forming a conductive structure over the insulating layer by:
forming a first conductive layer;
performing a degassing preparation process over a surface of the first conductive layer to substantially prevent a degassing of the first conductive layer from reaching a second conductive layer; and
forming the second conductive layer over the first conductive layer.

2. The method of fabricating the semiconductor device of claim 1, wherein the conductive structure is a floating gate.

3. The method of fabricating the semiconductor device of claim 1, wherein the first and second conductive layers are polysilicon layers.

4. The method of fabricating the semiconductor device of claim 1, wherein the degassing preparation process comprises subjecting the first conductive layer to a high temperature process, the high temperature process operable to increase the rate of degassing.

5. The method of fabricating the semiconductor device of claim 4, wherein the high temperature process is an RTP or annealing process.

6. The method of fabricating the semiconductor device of claim 4, wherein the high temperature process is performed at a temperature of about 700 to 1100 Celsius.

7. The method of fabricating the semiconductor device of claim 4, further comprising performing a pre-cleaning process.

8. The method of fabricating the semiconductor device of claim 7, wherein the pre-cleaning process comprises applying an SC1 solution, an SC2 solution, and an HF solution to the surface of the first conductive layer.

9. The method of fabricating the semiconductor device of claim 8, wherein the SC1 solution includes NH₄OH, H₂O₂, and deionized water in a ratio between about 1/2 to about 4/1, and the applying the SC1 solution is performed at a temperature between about 15 to about 80 Celsius.

10. The method of fabricating the semiconductor device of claim 8, wherein the SC2 solution includes HCl, H₂O₂, and deionized water in a ratio between about 1/2 to about 4/1, and the applying the SC2 solution is performed at a temperature between about 15 to about 80 Celsius.

11. The method of fabricating the semiconductor device of claim 8, wherein the HF solution includes about 49% concentration of HF and deionized water in a ratio between about 1/50 to about 1/500, and the applying the HF solution is performed at a temperature between about 15 to about 45 Celsius.

12. The method of fabricating the semiconductor device of claim 1, wherein the degassing preparation process comprises performing a pre-cleaning process by applying either of an SC1 solution and an SC2 solution to the surface of the first conductive layer as a last step of the pre-cleaning process.

13. The method of fabricating the semiconductor device of claim 12, wherein the SC1 solution includes NH₄OH, H₂O₂, and deionized water in a ratio between about 1/2 to about 4/1, and the applying the SC1 solution is performed at a temperature between about 15 to about 80 Celsius.

14. The method of fabricating the semiconductor device of claim 12, wherein the SC2 solution includes HCl, H₂O₂, and deionized water in a ratio between about 1/2 to about 4/1, and the applying the SC2 solution is performed at a temperature between about 15 to about 80 Celsius.

15. The method of fabricating the semiconductor device of claim 1, wherein the degassing preparation process comprises forming an oxide interface over the first conductive layer.

16. The method of fabricating the semiconductor device of claim 13, wherein the forming the oxide interface includes applying a solution of O₃ and deionized water, the solution having a concentration of O₃ of about 5 to about 100 ppm, and wherein the forming is performed at a temperature between about 15 to about 80 Celsius.
